(19) United States
(12) Patent Application Publication
(10) Pub. No.: US 2025/0336735 A1
(43) Pub. Date: Oct. 30, 2025

(54) SEMICONDUCTOR PACKAGE

(71) Applicant: SAMSUNG ELECTRONICS CO.,LTD., Suwon-si (KR)

(72) Inventor: Sehyeon PARK, Suwon-si (KR)

(73) Assignee: SAMSUNG ELECTRONICS CO.,LTD., Suwon-si (KR)

(21) Appl. No.: 18/904,748

(22) Filed: Oct. 2, 2024

(30) Foreign Application Priority Data
Apr. 29, 2024 (KR) 10-2024-0056889

(51) Int. Cl. H01L 23/13; H01L 21/48; H01L 23/00; H01L 23/31; H01L 23/498; H01L 25/065; H01L 25/10; H01L 25/18; H10B 80/00

(52) U.S. Cl. CPC H01L 23/13; H01L 21/4846; H01L 23/3128; H01L 23/3135; H01L 23/49816; H01L 23/49833; H01L 23/49838; H01L 24/16; H01L 24/17; H01L 24/81; H01L 25/0655; H01L 25/105; H01L 25/18; H01L 24/32; H01L 24/48; H01L 24/73; H01L 2224/16227; H01L 2224/1703; H01L 2224/32225; H01L 2224/48227; H01L 2224/73204; H01L 2224/81193; H01L 2224/81815; H01L 2924/301; H10B 80/00

(57) ABSTRACT

A semiconductor package includes a package substrate, an interposer substrate on the package substrate, a first semiconductor chip on the interposer substrate, a first connection terminal between the package substrate and the first semiconductor chip, and a second connection terminal between the interposer substrate and the first semiconductor chip. The interposer substrate includes a cavity. The first connection terminal is inside the cavity.

### CROSS-REFERENCE TO RELATED APPLICATIONS

This application claims benefit of priority under 35 U.S.C § 119 to Korean Patent Application No. 10-2024-0056889, filed on Apr. 29, 2024, in the Korean Intellectual Property Office, the disclosure of which is incorporated by reference herein in its entirety.

### BACKGROUND

### 1. Field

The present disclosure relates generally to a semiconductor package, and more particularly, to a semiconductor package including an interposer substrate.

### 2. Description of Related Art

Recently, there may be an increasing demand for reductions in size and/or weight of electronic parts that may be mounted and/or installed in electronic devices such as, but not limited to, portable devices. In order to potentially address a need for reducing the size and/or weight of electronic parts, there may exist a need for semiconductor packaging technology to integrate a number of individual devices into a single package, as well as, semiconductor technology to reduce the size and/or weight of individual semiconductor devices mounted in the packages. For example, a semiconductor package, in which a plurality of devices are integrated, may need to have a compact size, enhanced thermal characteristics, improved electrical properties, or the like, when compared to related semiconductor packages.

### SUMMARY

One or more example embodiments of the present disclosure provide a semiconductor package with improved electrical characteristics, when compared to related semiconductor packages, and a method of fabricating the same.

According to an aspect of the present disclosure, a semiconductor package includes a package substrate, an interposer substrate on the package substrate, a first semiconductor chip on the interposer substrate, a first connection terminal between the package substrate and the first semiconductor chip, and a second connection terminal between the interposer substrate and the first semiconductor chip. The interposer substrate includes a cavity. The first connection terminal is inside the cavity.

According to an aspect of the present disclosure, a semiconductor package includes a package substrate, an interposer substrate on the package substrate, a semiconductor chip on the interposer substrate, a first connection terminal between the package substrate and the semiconductor chip, and a second connection terminal between the interposer substrate and the semiconductor chip. A first height of the first connection terminal is greater than a second height of the second connection terminal. The first connection terminal is spaced apart from a lateral surface of the interposer substrate in a first direction parallel to a top surface of the package substrate.

According to an aspect of the present disclosure, a semiconductor package includes a package substrate, an interposer substrate on the package substrate, a first semiconductor chip on the interposer substrate, a second semiconductor chip on the interposer substrate and spaced apart from the first semiconductor chip in a first direction, a plurality of first connection terminals between the package substrate and the first semiconductor chip and between the package substrate and the second semiconductor chip, and a plurality of second connection terminals between the interposer substrate and the first semiconductor chip and between the interposer substrate and the second semiconductor chip. The interposer substrate includes a cavity on a center of the interposer substrate. The package substrate includes a plurality of substrate pads on a first top surface of the package substrate. The interposer substrate includes a plurality of interposer pads on a second top surface of the interposer substrate. The first semiconductor chip includes a plurality of first chip pads on a first bottom surface of the first semiconductor chip. The second semiconductor chip includes a plurality of second chip pads on a second bottom surface of the second semiconductor chip. The plurality of first connection terminals are in contact with the plurality of substrate pads, a portion of the plurality of first chip pads, and a portion of the plurality of second chip pads. The plurality of second connection terminals are in contact with the plurality of interposer pads, a remaining portion of the plurality of first chip pads excluding the portion of the plurality of the first chip pads, and a remaining portion of the plurality of second chip pads excluding the portion of the plurality of second chip pads. The plurality of first connection terminals are inside the cavity. The plurality of second connection terminals are outside the cavity.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 illustrates a plan view showing a semiconductor package, according to some embodiments;

FIG. 2 illustrates a cross-sectional view taken along line A-A′ of FIG. 1, according to some embodiments;

FIG. 3 illustrates a cross-sectional view taken along line I-I′ of FIG. 1, showing a semiconductor package, according to some embodiments;

FIG. 4 illustrates a cross-sectional view taken along line A-A′ of FIG. 1, showing a semiconductor device, according to some embodiments; and

FIGS. 5 to 8 illustrate cross-sectional views showing a method of fabricating a semiconductor package, according to some embodiments.

### DETAILED DESCRIPTION OF EMBODIMENTS

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

Hereinafter, various embodiments of the present disclosure are described with reference to the accompanying drawings.

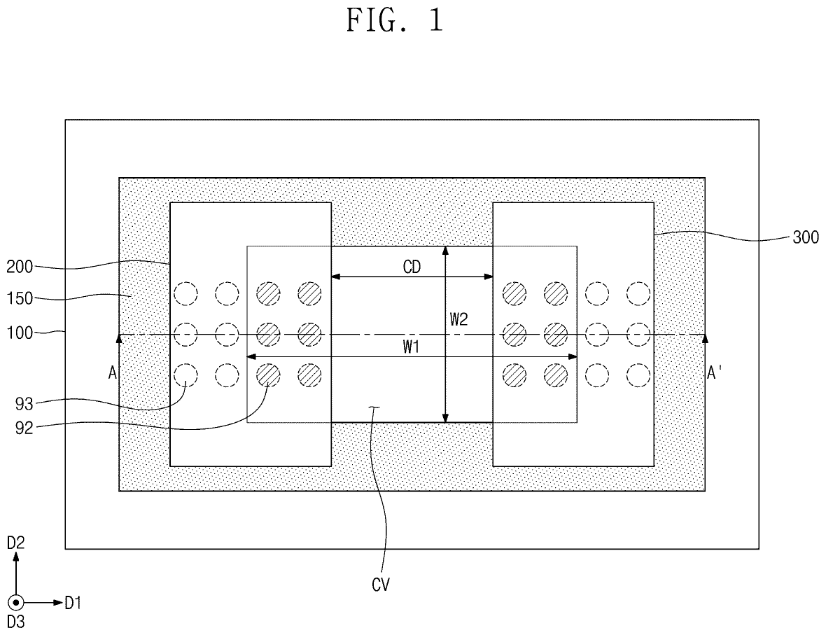

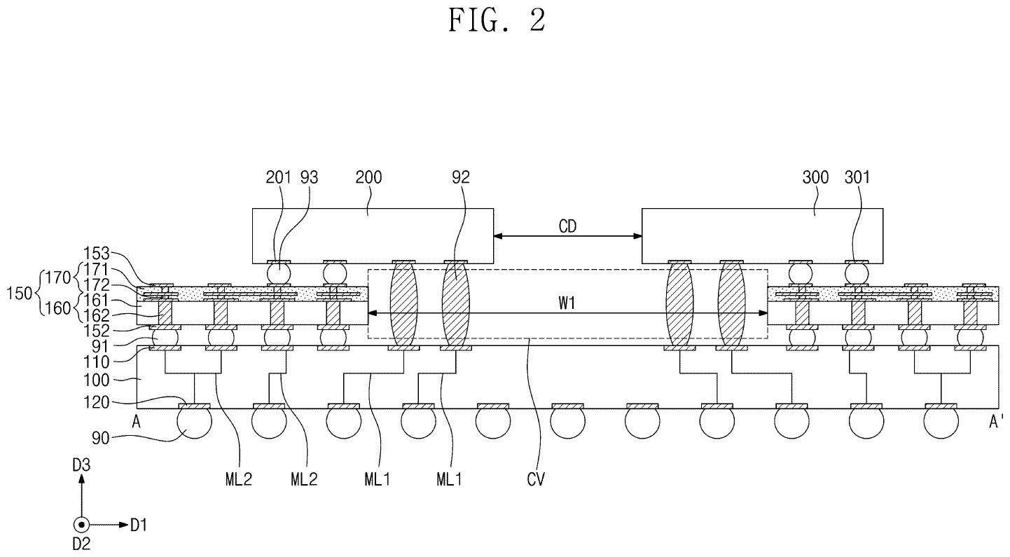

FIG. 1 illustrates a plan view showing a semiconductor package, according to some embodiments. FIG. 2 illustrates a cross-sectional view taken along line A-A′ of FIG. 1, according to some embodiments.

Referring to FIGS. 1 and 2, a semiconductor package may include a package substrate 100, an interposer substrate 150, a first semiconductor chip 200, and a second semiconductor chip 300.

The package substrate 100 may be and/or may include, for example, a printed circuit board (PCB). Alternatively or additionally, the package substrate 100 may have a structure in which at least one dielectric layer and at least one wiring layer are alternately stacked. The package substrate 100 may include a plurality of first substrate pads 110 on a top surface thereof. The package substrate 100 may also include a plurality of second substrate pads 120, first metal lines ML1, and second metal lines ML2 on a bottom surface thereof.

External connection terminals 90 may be correspondingly disposed on the plurality of second substrate pads 120. The external connection terminals 90 may be electrically connected through the plurality of second substrate pads 120 to the plurality of first substrate pads 110 and a wiring layer in the package substrate 100. The external connection terminals 90 may be and/or may include, but not be limited to, solder balls, solder bumps, or the like. Based on a type and/or arrangement of the external connection terminals 90, the external connection terminals 90 may be provided in the form of a ball grid array (BGA) type, a fine ball-grid array (FBGA) type, or a land grid array (LGA) type. The external connection terminal 90 may be an alloy that may include, but not be limited to, at least one of tin (Sn), silver (Ag), copper (Cu), nickel (Ni), bismuth (Bi), indium (In), antimony (Sb), cerium (Ce), or the like.

The interposer substrate 150 may be disposed on the package substrate 100. The interposer substrate 150 may have a cavity CV on a center thereof when viewed in a plan view. As used herein, the cavity CV may refer to an empty space formed within the interposer substrate 150. When viewed in the plan view, the cavity CV may have an area that is about 30% to about 60% of an area of the interposer substrate 150. In an embodiment, as the cavity CV is positioned on the center of the interposer substrate 150, the top surface of the package substrate 100 may be partially exposed.

The cavity CV may have a first width W1 along a first direction D1. The cavity CV may have a second width W2 along a second direction D2. The first width W1 may be about 60% to about 80% of a length in the first direction D1 of the interposer substrate 150. The second width W2 may be about 50% to about 75% of a length in the second direction D2 of the interposer substrate 150.

As used herein, the first direction D1 may refer to a direction parallel to the top surface of the package substrate 100. The second direction D2 may refer to another direction parallel to the top surface of the package substrate 100 that is orthogonal to the first direction D1. A third direction D3 may refer to a direction perpendicular to the top surface of the package substrate 100.

The interposer substrate 150 may include an interposer core layer 160 and an interposer wiring layer 170. The interposer core layer 160 may include a core substrate 161 and interposer vias 162 that may vertically penetrate the core substrate 161. The core substrate 161 may be and/or may include a semiconductor substrate, and for example, may be a silicon (Si) substrate. However, the present disclosure is not limited in this regard. A plurality of interposer vias 162 may be provided along the first direction D1.

The interposer wiring layer 170 may be disposed on the interposer core layer 160. For example, the interposer core layer 160 may be disposed closer than the interposer wiring layer 170 to the package substrate 100. The interposer wiring layer 170 may include an interposer dielectric layer 171 and wiring patterns 172 in the interposer dielectric layer 171. The wiring patterns 172 may be electrically connected to the interposer vias 162. The interposer dielectric layer 171 may include a dielectric material, such as, but not limited to, silicon oxide (SiO), silicon nitride (SiN), or the like. The wiring patterns 172 may include a metallic material, such as, but not limited to, copper (Cu).

The interposer substrate 150 may include upper interposer pads 153 disposed on a top surface of the interposer substrate 150 and lower interposer pads 152 disposed on a bottom surface of the interposer substrate 150. The upper interposer pads 153 may be exposed from the top surface of the interposer substrate 150. The lower interposer pads 152 may be exposed from the bottom surface of the interposer substrate 150.

First connection terminals 91 may be disposed between the package substrate 100 and the interposer substrate 150. For example, the first connection terminals 91 may be interposed between and in contact with the lower interposer pads 152 and the first substrate pads 110. The first connection terminals 91 may include a metallic material that may be substantially similar and/or the same as the material of the external connection terminals 90. For example, the first connection terminals 91 may include, but not be limited to, tin (Sn), bismuth (Bi), lead (Pb), silver (Ag), or any alloy thereof.

The first semiconductor chip 200 and the second semiconductor chip 300 may be disposed spaced apart from each other in the first direction D1 on the interposer substrate 150. A lateral surface of the first semiconductor chip 200 may face a lateral surface of the second semiconductor chip 300. The first semiconductor chip 200 and the second semiconductor chip 300 may each have portions that may overlap in the third direction D3 with the interposer substrate 150. The first semiconductor chip 200 and the second semiconductor chip 300 may each have remaining portions that may overlap in the third direction D3 with the package substrate 100 and the cavity CV. A minimum spacing distance D in the first direction D1 between the first semiconductor chip 200 and the second semiconductor chip 300 may be less than the first width W1 of the cavity CV. For example, the minimum spacing distance D in the first direction D1 between the first semiconductor chip 200 and the second semiconductor chip 300 may be about 25% to about 50% of the first width W1.

The type of the first semiconductor chip 200 and the type of the second semiconductor chip 300 may the same chip type and/or may be different chip types. The first semiconductor chip 200 and the second semiconductor chip 300 may be, for example, a logic chip, a memory chip, or the like. As another example, the first semiconductor chip 200 and the second semiconductor chip 300 may each be at least one of a central processing unit (CPU), a graphic processing unit (GPU), an application specific integrated circuit (ASIC), a dynamic random access memory (DRAM), a static random access memory (SRAM), an NAND Flash memory, or the like. However, the present disclosure is not limited in this regard. That is, the types of the first semiconductor chip 200 and the second semiconductor chip 300 may be the same as each other, different from other, or of another type not listed above.

A plurality of first chip pads 201 may be disposed on a bottom surface of the first semiconductor chip 200, and a plurality of second chip pads 301 may be disposed on a bottom surface of the second semiconductor chip 300. Second connection terminals 92 may be disposed between the first semiconductor chip 200 and the package substrate 100 and between the second semiconductor chip 300 and the package substrate 100. A plurality of second connection terminals 92 may be disposed in the first direction D1 and/or the second direction D2. The second connection terminals 92 may be disposed inside the cavity CV of the interposer substrate 150. For example, the second connection terminals 92 may be disposed spaced apart in the first direction D1 from a lateral surface of the interposer substrate 150. The second connection terminals 92 may be interposed between and in contact with the first substrate pads 110 and the first chip pads 201, and may be interposed between and in contact with the first substrate pads 110 and the second chip pads 301. The second connection terminals 92 may be electrically connected to the external connection terminals 90 through the first metal lines ML1 connected to the first and second substrate pads 110 and 120 of the package substrate 100. The second connection terminals 92 may include a metallic material that may be substantially similar and/or the same as the material of the external connection terminals 90. For example, the second connection terminals 92 may include, but not be limited to, tin (Sn), bismuth (Bi), lead (Pb), silver (Ag), or any alloy thereof.

Third connection terminals 93 may be disposed between the first semiconductor chip 200 and the interposer substrate 150 and between the second semiconductor chip 300 and the interposer substrate 150. A plurality of third connection terminals 93 may be disposed in the first direction D1 and/or the second direction D2. The third connection terminals 93 may be disposed outside the cavity CV of the interposer substrate 150. For example, the third connection terminals 93 may vertically overlap the interposer substrate 150. A height in the third direction D3 of the second connection terminals 92 may be greater than a height in the third direction D3 of the third connection terminals 93.

The third connection terminals 93 may be interposed between and in contact with the upper interposer pads 153 and the first chip pads 201, and may be interposed between and in contact with the upper interposer pads 153 and the second chip pads 301. The third connection terminals 93 may be electrically connected to the external connection terminals 90 through the interposer substrate 150, the first connection terminals 91, and the second metal lines ML2 connected to the first and second substrate pads 110 and 120 of the package substrate 100. For example, the second connection terminals 92 and the third connection terminals 93 may be electrically connected to the external connection terminals 90 through the first metal lines ML1 and the second metal lines ML2, respectively.

According to some embodiments, the first metal line ML1 and the second metal line ML2 may not be electrically connected to each other. The third connection terminals 93 may include a metallic material that may be substantially similar and/or the same as the material of the external connection terminals 90. For example, the third connection terminals 93 may include tin, but not be limited to, (Sn), bismuth (Bi), lead (Pb), silver (Ag), or any alloy thereof.

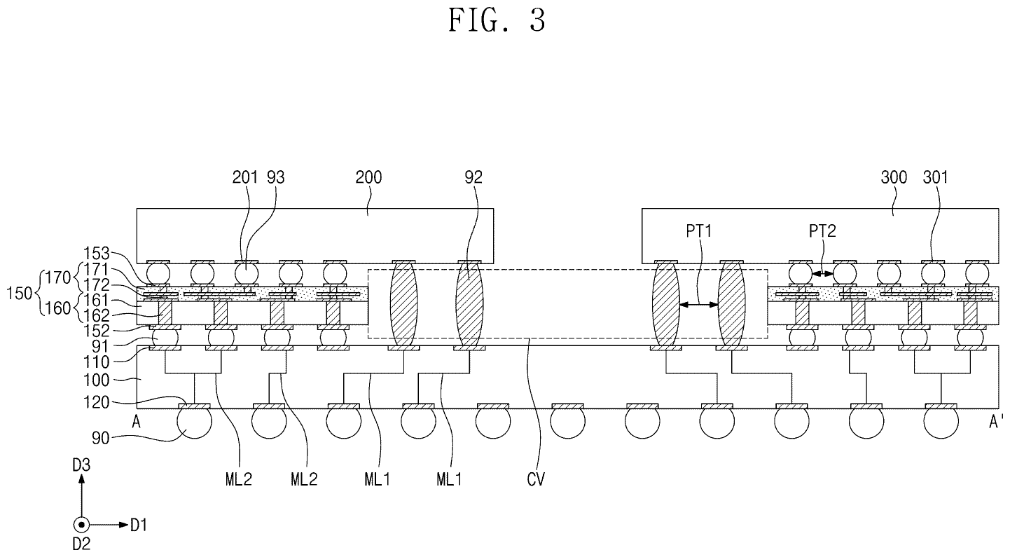

FIG. 3 illustrates a cross-sectional view taken along line I-I′ of FIG. 1, showing a semiconductor package, according to some embodiments. The semiconductor package of FIG. 3 may include and/or may be similar in many respects to the semiconductor package described above with reference to FIG. 2, and may include additional features not mentioned above. Consequently, repeated descriptions of the semiconductor package described above with reference to FIG. 2 may be omitted for the sake of brevity.

Referring to FIG. 3, the number of the third connection terminals 93 may be greater than the number of the second connection terminals 92, and the number of the third connection terminals 93 is not limited to that shown in FIG. 3. Thus, a region where the first semiconductor chip 200 and the second semiconductor chip 300 overlap in the third direction D3 with the interposer substrate 150 may be greater than a region where the first semiconductor chip 200 and the second semiconductor chip 300 overlap in the third direction D3 with the package substrate 100.

A first pitch PT1 between the second connection terminals 92 may be greater than a second pitch PT2 between the third connection terminals 93. As used herein, the first pitch PT1 may correspond to a minimum spacing distance in the first direction D1 between the second connection terminals 92. The second pitch PT2 may correspond to a minimum spacing distance in the first direction D1 between the third connection terminals 93.

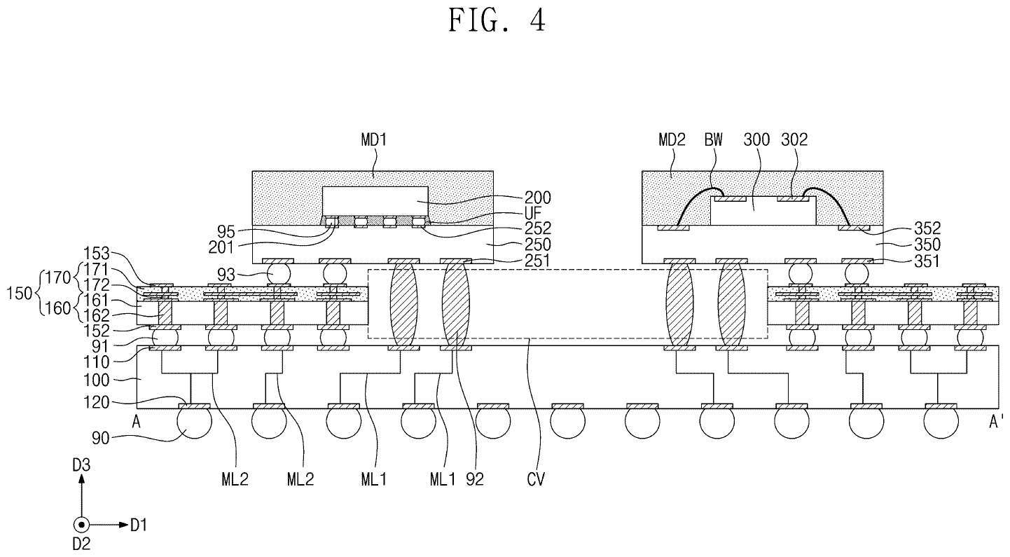

FIG. 4 illustrates a cross-sectional view taken along line A-A′ of FIG. 1, showing a semiconductor device, according to some embodiments. The semiconductor package of FIG. 4 may include and/or may be similar in many respects to the semiconductor package described above with reference to FIG. 2, and may include additional features not mentioned above. Consequently, repeated descriptions of the semiconductor package described above with reference to FIG. 2 may be omitted for the sake of brevity.

Referring to FIG. 4, a first sub-package substrate 250 may be disposed between the interposer substrate 150 and the first semiconductor chip 200. The first sub-package substrate 250 may be and/or may include, for example, a PCB. Alternatively additionally, the first sub-package substrate 250 may be a redistribution substrate including a plurality of stacked dielectric layers and redistribution patterns.

The first sub-package substrate 250 may include a plurality of first sub-substrate pads 252 on a top surface thereof and a plurality of second sub-substrate pads 251 on a bottom surface thereof. Some of the second sub-substrate pads 251 may be in contact with the second connection terminals 92. Others of the second sub-substrate pads 251 may be in contact with the third connection terminals 93.

Chip connection terminals 95 may be disposed between the first sub-package substrate 250 and the first semiconductor chip 200. For example, the chip connection terminals 95 may be interposed between and in contact with the first sub-substrate pads 252 and the first chip pads 201. The chip connection terminals 95 may include a metallic material that may be substantially similar and/or the same as to a material of the external connection terminals 90. For example, the chip connection terminals 95 may include, but not be limited to, tin (Sn), bismuth (Bi), lead (Pb), silver (Ag), or any alloy thereof.

An underfill layer UF may be provided between the first sub-package substrate 250 and the first semiconductor chip 200. The underfill layer UF may fill a space between the first sub-package substrate 250 and the first semiconductor chip 200 and may surround a lateral surface of each of the chip connection terminals 95. The underfill layer UF may include, for example, an epoxy resin. However, the present disclosure is not limited in this regard.

A first molding layer MD1 may be provided to cover a top surface of the first sub-package substrate 250, lateral and top surfaces of the first semiconductor chip 200, and a lateral surface of the underfill layer UF. The first molding layer MD1 may include a dielectric material, and the dielectric material may include either a material such as an epoxy molding compound (EMC), for example, or an adhesive material.

A second sub-package substrate 350 may be disposed between the interposer substrate 150 and the second semiconductor chip 300. The second sub-package substrate 350 may be and/or may include, for example, a PCB. Alternatively or additionally, the second sub-package substrate 350 may be and/or may include a redistribution substrate including a plurality of stacked dielectric layers and redistribution patterns. The second sub-package substrate 350 may include a plurality of third sub-substrate pads 352 on a top surface thereof and a plurality of fourth sub-substrate pads 351 on a bottom surface thereof. Some of the fourth sub-substrate pads 351 may be in contact with the second connection terminals 92. Others of the fourth sub-substrate pads 351 may be in contact with the third connection terminals 93.

Chip connection pads 302 disposed on one surface of the second semiconductor chip 300 may be connected through bonding wires BW to the third sub-substrate pads 352 of the second sub-package substrate 350.

A second molding layer MD2 may be provided to cover a top surface of the second sub-package substrate 350 and lateral and top surfaces of the second semiconductor chip 300. The second molding layer MD2 may include a dielectric material, and the dielectric material may include either a material such as an epoxy molding compound (EMC), for example, or an adhesive material.

As shown in FIG. 4, the first semiconductor chip 200 may be electrically connected through the chip connection terminals 95 to the first sub-package substrate 250, and the second semiconductor chip 300 may be electrically connected through the bonding wires BW to the second sub-package substrate 350. However, the present disclosure is not limited thereto. For example, the first semiconductor chip 200 may be electrically connected through the bonding wires BW to the first sub-package substrate 250, and the second semiconductor chip 300 may be electrically connected through the chip connection terminals 95 to the second sub-package substrate 350.

In a semiconductor package, according to some embodiments, an interposer substrate 150 may have a cavity. In some embodiments, semiconductor chips may be directly connected to a package substrate 100 through connection terminals disposed inside the cavity, and may be directly connected to the interposer substrate 150 through connection terminals disposed outside the cavity. In such a case, the semiconductor chips and the package substrate 100 may be electrically directly connected, without means of the interposer substrate 150, through the connection terminals disposed inside the cavity. As such, there may be an increase in electrical signal transfer speed between the semiconductor chip and the package substrate 100. In addition, as the semiconductor chips are electrically connected to each other through the interpose substrate, the semiconductor package have improved electrical characteristics, when compared to a related semiconductor package.

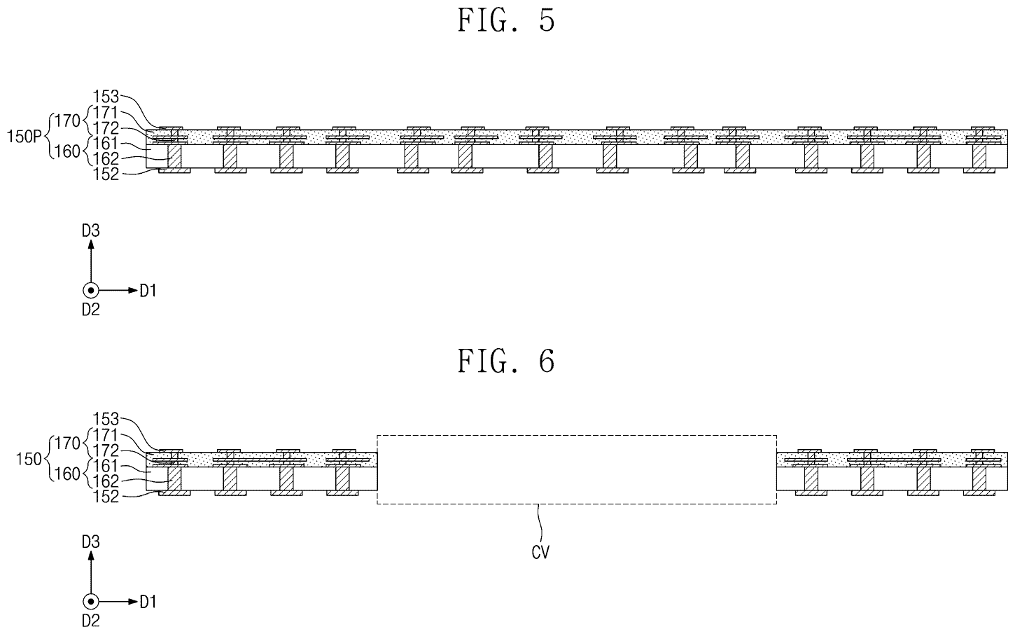

FIGS. 5 to 8 illustrate cross-sectional views showing a method of fabricating a semiconductor package, according to some embodiments. FIGS. 5 to 8 show cross-sectional views showing a method of fabricating the semiconductor package depicted in FIG. 2.

Referring to FIG. 5, a preliminary interposer substrate 150P may be provided. The preliminary interposer substrate 150P may include an interposer core layer 160 and an interposer wiring layer 170. In addition, the preliminary interposer substrate 150P may include upper interposer pads 153 disposed on a top surface of the preliminary interposer substrate 150P and lower interposer pads 152 disposed on a bottom surface of the preliminary interposer substrate 150P.

Referring to FIG. 6, a portion of the preliminary interposer substrate 150P may be removed to form a cavity CV. As a result, the preliminary interposer substrate 150P may be formed into an interposer substrate 150 having the cavity CV. The formation of the cavity CV may expose an inner lateral surface of the interposer substrate 150.

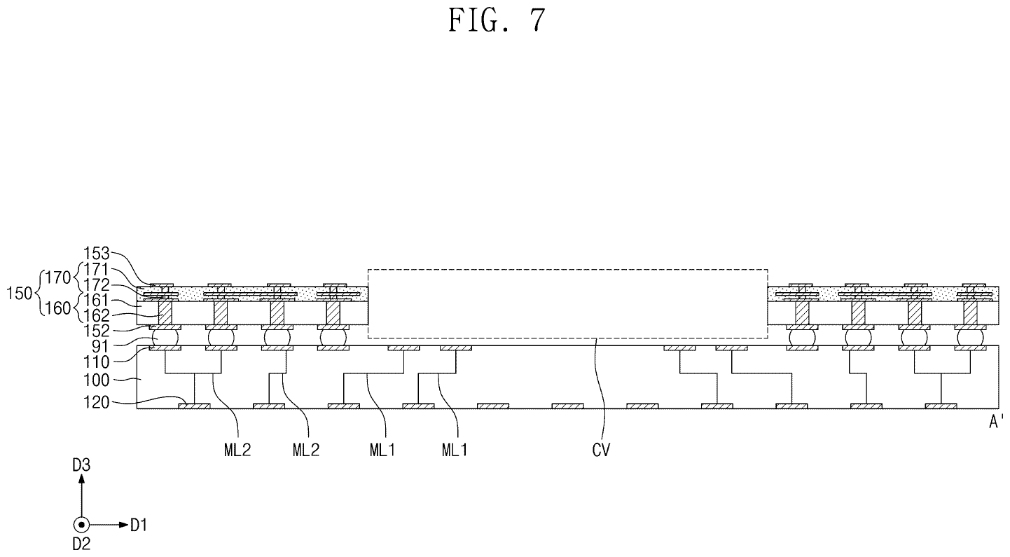

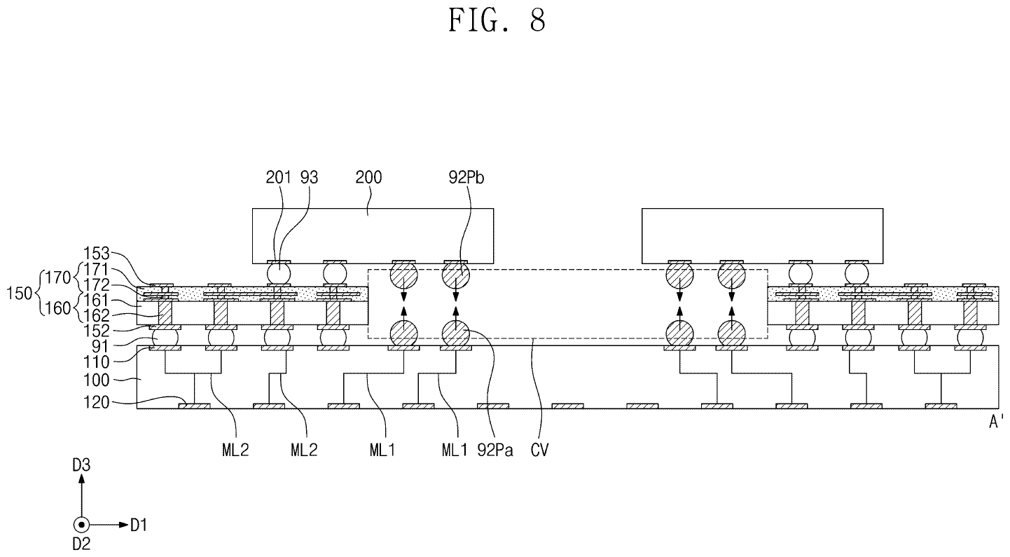

Referring to FIG. 7, a package substrate 100 may be provided below the interposer substrate 150. The package substrate 100 may include a plurality of first substrate pads 110 on a top surface thereof and a plurality of second substrate pads 120 and first and second metal lines ML1 and ML2 on a bottom surface thereof. The interposer substrate 150 may be connected through first connection terminals 91 to the package substrate 100. The cavity CV of the interposer substrate 150 may expose a portion of the top surface of the package substrate 100.

Referring to FIG. 8, preliminary lower connection terminals 92Pa may be provided on the top surface of the package substrate 100 exposed by the cavity CV. The preliminary lower connection terminals 92Pa may be disposed on the first substrate pads 110. Thereafter, a first semiconductor chip 200 and a second semiconductor chip 300 may be mounted on the interposer substrate 150. Third connection terminals 93 and preliminary upper connection terminals 92Pb may be provided on a bottom surface of each of the first semiconductor chip 200 and the second semiconductor chip 300. The third connection terminals 93 may be correspondingly in contact with the upper interposer pads 153. The preliminary upper connection terminal 92Pb and the preliminary lower connection terminal 92Pa may be connected into a single unitary piece in a reflow process. The reflow process may be performed at a temperature equal to or greater than melting points of the preliminary upper connection terminals 92Pb and the preliminary lower connection terminals 92Pa. In the reflow process, the preliminary upper connection terminals 92Pb and the preliminary lower connection terminals 92Pa may be connected to form second connection terminals 92 as discussed with reference to FIG. 2.

The external connection terminals 90 may be attached to the second substrate pads 120 positioned on the bottom surface of the package substrate 100, and accordingly, a semiconductor package may be obtained as shown in FIG. 2.

In a semiconductor package, according to some embodiments, an interposer substrate 150 may have a cavity. A semiconductor chip and a package substrate 100 may be directly electrically connected, without means of the interposer substrate 150, through connection terminals disposed inside the cavity. As a result, there may be an increase in electrical signal transfer speed between the semiconductor chip and the package substrate 100. In addition, as the semiconductor chips are electrically connected to each other through the interpose substrate, the semiconductor package have improved electrical characteristics, when compared to a related semiconductor package.

Although the present disclosure has been described in connection with some embodiments of the present disclosure illustrated in the accompanying drawings, it is to be understood to those skilled in the art that various changes and modifications may be made without departing from the technical spirit and essential feature of the present disclosure. It is to be apparent to those skilled in the art that various substitution, modifications, and changes may be thereto without departing from the scope and spirit of the present disclosure.

What is claimed is:

1. A semiconductor package, comprising:
a package substrate;
an interposer substrate on the package substrate;
a first semiconductor chip on the interposer substrate;
a first connection terminal between the package substrate and the first semiconductor chip; and
a second connection terminal between the interposer substrate and the first semiconductor chip,
wherein the interposer substrate comprises a cavity, and
wherein the first connection terminal is inside the cavity.

2. The semiconductor package of claim 1, wherein the second connection terminal is outside the cavity.

3. The semiconductor package of claim 1, wherein, in a plan view, a first area of the cavity is 30% to 60% of a second area of the interposer substrate.

4. The semiconductor package of claim 1, wherein the cavity has a first width in a first direction parallel to a top surface of the package substrate, and
wherein the first width is 60% to 80% of a first length in the first direction of the interposer substrate.

5. The semiconductor package of claim 4, wherein the cavity has a second width in a second direction, the second direction being parallel to the top surface of the package substrate and orthogonal to the first direction, and
wherein the second width is 50% to 75% of a second length in the second direction of the interposer substrate.

6. The semiconductor package of claim 4, further comprising:
a second semiconductor chip on the interposer substrate,
wherein a second lateral surface of the second semiconductor chip is directed toward a first lateral surface of the first semiconductor chip,
wherein a first portion of the first semiconductor chip vertically overlaps the cavity,
wherein a second portion of the second semiconductor chip vertically overlaps the cavity.

7. The semiconductor package of claim 6, wherein a minimum spacing distance in the first direction between the first semiconductor chip and the second semiconductor chip is 25% to 50% of the first width.

8. The semiconductor package of claim 1, wherein the first semiconductor chip comprises a chip pad on a bottom surface of the first semiconductor chip,
wherein the package substrate comprises a substrate pad on a first top surface of the package substrate, and
wherein the first connection terminal is in contact with the chip pad and the substrate pad.

9. The semiconductor package of claim 8, wherein the interposer substrate comprises an interposer substrate pad on a second top surface of the interposer substrate, and
wherein the second connection terminal is in contact with the interposer substrate pad and the chip pad.

10. A semiconductor package, comprising:
a package substrate;
an interposer substrate on the package substrate;
a semiconductor chip on the interposer substrate;
a first connection terminal between the package substrate and the semiconductor chip; and
a second connection terminal between the interposer substrate and the semiconductor chip,
wherein a first height of the first connection terminal is greater than a second height of the second connection terminal, and
wherein the first connection terminal is spaced apart from a lateral surface of the interposer substrate in a first direction parallel to a top surface of the package substrate.

11. The semiconductor package of claim 10, wherein the interposer substrate comprises a cavity, and
wherein a portion of the top surface of the package substrate is exposed by the cavity.

12. The semiconductor package of claim 10, further comprising:
a sub-package substrate between the semiconductor chip and the interposer substrate; and
a molding layer on the sub-package substrate and at least partially covering the semiconductor chip.

13. The semiconductor package of claim 12, further comprising:
a chip connection terminal between the sub-package substrate and the semiconductor chip.

14. The semiconductor package of claim 12, further comprising:
a bonding wire coupling the sub-package substrate with the semiconductor chip.

15. A semiconductor package, comprising:
a package substrate;
an interposer substrate on the package substrate, the interposer substrate comprising a cavity on a center of the interposer substrate;
a first semiconductor chip on the interposer substrate;
a second semiconductor chip on the interposer substrate and spaced apart from the first semiconductor chip in a first direction;
a plurality of first connection terminals between the package substrate and the first semiconductor chip and between the package substrate and the second semiconductor chip; and
a plurality of second connection terminals between the interposer substrate and the first semiconductor chip and between the interposer substrate and the second semiconductor chip,
wherein the package substrate comprises a plurality of substrate pads on a first top surface of the package substrate,
wherein the interposer substrate comprises a plurality of interposer pads on a second top surface of the interposer substrate,
wherein the first semiconductor chip comprises a plurality of first chip pads on a first bottom surface of the first semiconductor chip,
wherein the second semiconductor chip comprises a plurality of second chip pads on a second bottom surface of the second semiconductor chip,
wherein the plurality of first connection terminals are in contact with the plurality of substrate pads, a portion of the plurality of first chip pads, and a portion of the plurality of second chip pads,
wherein the plurality of second connection terminals are in contact with the plurality of interposer pads, a remaining portion of the plurality of first chip pads excluding the portion of the plurality of the first chip pads, and a remaining portion of the plurality of second chip pads excluding the portion of the plurality of second chip pads,
wherein the plurality of first connection terminals are inside the cavity, and
wherein the plurality of second connection terminals are outside the cavity.

16. The semiconductor package of claim 15, wherein a second number of the plurality of second connection terminals is greater than a first number of the plurality of first connection terminals.

17. The semiconductor package of claim 16, wherein a first region where the interposer substrate and the first semiconductor chip at least partially vertically overlap each other is greater than a second region where the package substrate and the first semiconductor chip at least partially vertically overlap each other.

18. The semiconductor package of claim 16, wherein a first minimum spacing distance in the first direction between the plurality of first connection terminals is greater than a second minimum spacing distance in the first direction between the plurality of second connection terminals,
wherein the first direction is parallel to the first top surface of the package substrate.

19. The semiconductor package of claim 15, wherein a first portion of the first semiconductor chip overlaps the cavity, and
wherein a second portion of the second semiconductor chip vertically overlaps the cavity.

20. The semiconductor package of claim 15, wherein a first area of the cavity is 30% to 60% of a second area of the interposer substrate.
